(19) United States
(12) Patent Application Publication
(10) Pub. No.: US 2026/0047279 A1
(43) Pub. Date: Feb. 12, 2026

(54) DISPLAY DEVICE

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 19/290,404

(22) Filed: Aug. 5, 2025

(30) Foreign Application Priority Data
Aug. 6, 2024 (JP) 2024-130079

(51) Int. Cl. H10K 59/122; H10K 59/80; H10K 102/00

(52) U.S. Cl. CPC H10K 59/122; H10K 59/80521; H10K 2102/351

(57) ABSTRACT

A display device includes an organic insulating layer provided above a substrate, a rib layer covering an end portion of a lower electrode provided above the organic insulating layer and including a pixel aperture overlapping with the lower electrode, and a partition. The rib layer includes an upper layer which is in contact with a lower portion of the partition, a lower layer which covers the end portion of the lower electrode, an intermediate layer provided between the upper layer and the lower layer, and an inclined surface forming the pixel aperture. End portions of the upper layer and the lower layer protrude beyond an end portion of the intermediate layer, thereby forming a recess portion on the inclined surface.

### CROSS-REFERENCE TO RELATED APPLICATIONS

This application is based upon and claims the benefit of priority from Japanese Patent Application No. 2024-130079, filed Aug. 6, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In such display devices, a technique which can suppress the reduction in reliability has been required.

### BRIEF DESCRIPTION OF THE DRAWINGS

FIG. 1 is a view showing a configuration example of a display device of an embodiment.

FIG. 2 is a schematic plan view showing an example of a layout of subpixels.

FIG. 3 is a schematic cross-sectional view showing the display device along III-III line in FIG. 2.

FIG. 4 is a schematic cross-sectional view showing the display device along IV-IV line in FIG. 2.

FIG. 5 is a diagram showing an example of a layer structure that can be applied to organic layers shown in FIG. 3.

FIG. 6 is a schematic cross-sectional view showing the display device along V-V line in FIG. 2.

FIG. 7A is a schematic cross-sectional view showing a manufacturing process of the display device.

FIG. 7B is a schematic cross-sectional view showing a manufacturing process of the display device.

FIG. 7C is a schematic cross-sectional view showing a manufacturing process of the display device.

FIG. 7D is a schematic cross-sectional view showing a manufacturing process of the display device.

FIG. 7E is a schematic cross-sectional view showing a manufacturing process of the display device.

FIG. 7F is a schematic cross-sectional view showing a manufacturing process of the display device.

FIG. 8A is a schematic cross-sectional view showing a method of manufacturing the display device.

FIG. 8B is a schematic cross-sectional view showing the method of manufacturing the display device.

FIG. 8C is a schematic cross-sectional view showing the method of manufacturing the display device.

FIG. 8D is a schematic cross-sectional view showing the method of manufacturing the display device.

FIG. 8E is a schematic cross-sectional view showing the method of manufacturing the display device.

FIG. 8F is a schematic cross-sectional view showing the method of manufacturing the display device.

FIG. 9 is a schematic cross-sectional view showing a manufacturing process of the display device.

FIG. 10 is a cross-sectional view showing a display device of a comparative example.

FIG. 11 is a cross-sectional view showing the display device of the comparative example.

FIG. 12 is a schematic cross-sectional view showing another configuration example of the display device shown in FIG. 4.

### DETAILED DESCRIPTION

In general, according to one embodiment, there is provided a display device including a substrate, an organic insulating layer provided above the substrate, a lower electrode provided above the organic insulating layer, a rib layer covering an end portion of the lower electrode and including a pixel aperture overlapping with the lower electrode, an organic layer covering the lower electrode through the pixel aperture and emitting light in accordance with application of a voltage, an upper electrode covering the organic layer, and a partition including a lower portion provided on the rib layer and an upper portion having an end portion protruding from a side surface of the lower portion. The rib layer includes an upper layer which is in contact with the lower portion of the partition, a lower layer which covers the end portion of the lower electrode and which is in contact with the lower electrode, an intermediate layer provided between the upper layer and the lower layer, and an inclined surface forming the pixel aperture. End portions of the upper layer and the lower layer protrude beyond an end portion of the intermediate layer, thereby forming a recess portion on the inclined surface.

According to another embodiment, there is provided a display device including a substrate, an organic insulating layer provided above the substrate, a lower electrode provided above the organic insulating layer, a rib layer covering an end portion of the lower electrode and including a pixel aperture overlapping with the lower electrode, an organic layer covering the lower electrode through the pixel aperture and emitting light in accordance with application of a voltage, an upper electrode covering the organic layer, and a partition including a lower portion provided on the rib layer and an upper portion having an end portion protruding from a side surface of the lower portion. The rib layer includes an upper layer which is in contact with the lower portion of the partition, a lower layer which covers the end portion of the lower electrode and which is in contact with the lower electrode, an intermediate layer provided between the upper layer and the lower layer, and an inclined surface forming the pixel aperture. The intermediate layer includes a first intermediate layer which is in contact with the lower layer, a second intermediate layer which is in contact with the upper layer, and a third intermediate layer provided between the first intermediate layer and the second intermediate layer.

End portions of the lower layer and the third intermediate layer protrude beyond an end portion of the first intermediate layer, thereby forming a first recess portion on the inclined surface. End portions of the upper layer and the third intermediate layer protrude beyond an end portion of the second intermediate layer, thereby forming a second recess portion on the inclined surface.

According to this configuration, a display device capable of suppressing a reduction in reliability can be provided.

An embodiment will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective portions are illustrated schematically in the drawings, rather than as an accurate representation of what is implemented. However, such schematic illustration is merely exemplary, and in no way restricts the interpretation of the invention. Besides, in the specification and drawings, the same elements as those described in connection with preceding drawings are denoted by like reference numerals, and a detailed description thereof is omitted unless otherwise necessary.

In the drawings, an X-axis, a Y-axis and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is a normal direction relative to a plane including the X-direction and the Y-direction. In addition, viewing various elements parallel to the Z-direction is referred to as plan view.

The display device of the present embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

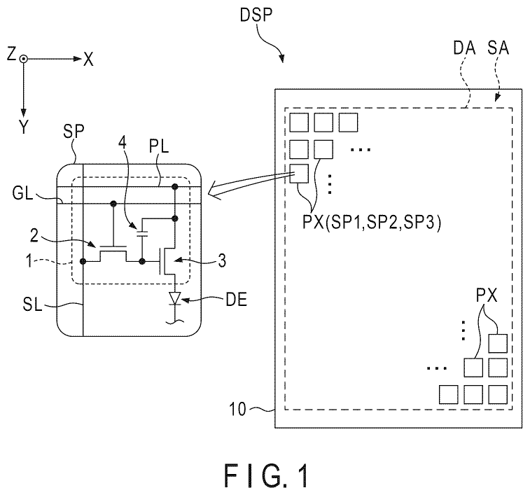

FIG. 1 is a diagram showing a configuration example of a display device DSP according to an embodiment.

The display device DSP comprises an insulating substrate 10. The substrate 10 has a display area DA where images are displayed, and a surrounding area SA around the display area DA. The substrate 10 may be glass or a resinous film having flexibility.

In the present embodiment, the substrate 10 has a rectangular shape as seen in plan view. However, the shape of the substrate 10 in plan view is not limited to a rectangular shape, but may be any other shape such as a square, a circle or an ellipse.

The display area DA comprises a plurality of pixels PX arrayed in matrix in the first direction X and the second direction Y. Each of the pixels PX includes a plurality of subpixels SP that display different colors. In the present embodiment, it is assumed that the pixel PX includes a blue subpixel SP1 (first subpixel), a green subpixel SP2 (second subpixel), and a red subpixel SP3 (third subpixel). However, the pixel PX may include a subpixel SP which exhibits the other color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements which consist of thin-film transistors.

A plurality of scanning lines GL which supply a scanning signal to the pixel circuit 1 of each subpixel SP, a plurality of signal lines SL which supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. A drain electrode of the drive transistor 3 is connected to the display element DE.

Incidentally, the configuration of the pixel circuit 1 is not limited to the example shown in the figure. For example, the pixel circuit 1 may comprise more thin-film transistors and more capacitors.

The display element DE is an organic light emitting diode (OLED) serving as a light emitting element, and is often referred to as an organic EL element.

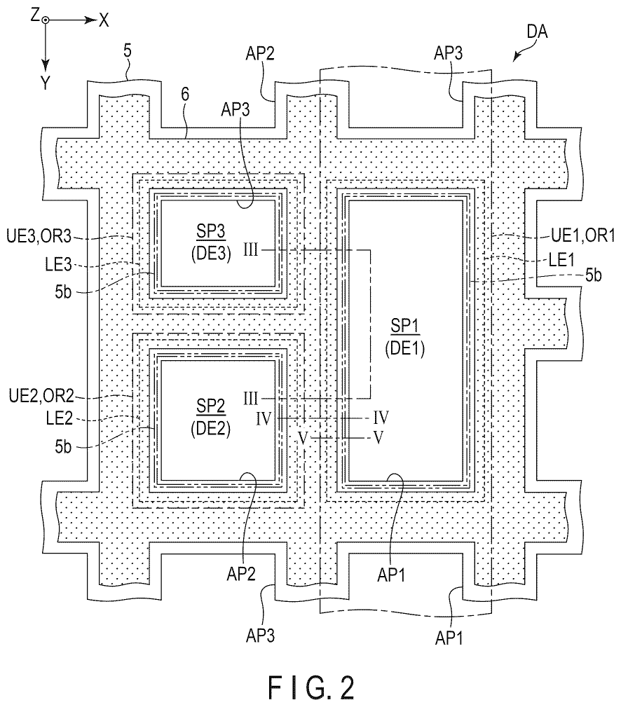

FIG. 2 is a schematic plan view showing an example of a layout of the subpixels SP1, SP2, and SP3.

In the example of FIG. 2, each of the subpixels SP2 and SP3 is arranged with the subpixel SP1 in the X-direction. Furthermore, the subpixels SP2 and SP3 are arranged in the Y-direction.

When the subpixels SP1, SP2, and SP3 are provided in this layout, a column in which the subpixels SP2 and SP3 are alternately provided in the Y-direction and a column in which a plurality of subpixels SP1 are repeatedly provided in the Y-direction are formed in the display area DA. These columns are alternately arranged in the X-direction. Incidentally, the layout of the subpixels SP1, SP2, and SP3 is not limited to the example in FIG. 2.

A rib layer 5 is provided in the display area DA. The rib layer 5 includes pixel apertures AP1, AP2, and AP3 in the subpixels SP1, SP2, and SP3, respectively. In the example in FIG. 2, the pixel aperture AP1 is larger than the pixel aperture AP2, and the pixel aperture AP2 is larger than the pixel aperture AP3. In other words, among the subpixels SP1, SP2, and SP3, the aperture ratio of the subpixel SP1 is the greatest, and the aperture ratio of the subpixel SP3 is the smallest. Incidentally, the sizes of the pixel apertures AP1, AP2, and AP3 are not limited to this example. For example, at least two of the pixel apertures AP1, AP2, and AP3 may have the same size.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

Parts of the lower electrode LE1, the upper electrode UE1, and the organic layer OR1, which overlap with the pixel aperture AP1, constitute the display element DE1 of the subpixel SP1. Parts of the lower electrode LE2, the upper electrode UE2, and the organic layer OR2, which overlap with the pixel aperture AP2, constitute the display element DE2 of the subpixel SP2. Parts of the lower electrode LE3, the upper electrode UE3, and the organic layer OR3, which overlap with the pixel aperture AP3, constitute the display element DE3 of the subpixel SP3. Each of the display elements DE1, DE2, and DE3 may further include a cap layer to be described later. The rib layer 5 surrounds each of these display elements DE1, DE2, and DE3.

A partition 6 is provided in the display area DA. The partition 6 is located above the rib layer 5 and overlaps with the rib layer 5 as a whole. In the example in FIG. 2, the partition 6 has a planar shape similar to that of the rib layer 5. In other words, the partition 6 comprises an aperture in each of the subpixels SP1, SP2, and SP3. From another viewpoint, each of the rib layer 5 and the partition 6 has a grating shape as seen in plan view, and surrounds each of the display elements DE1, DE2, and DE3. The partition 6 functions as lines which apply the common voltage to the upper electrodes UE1, UE2, and UE3.

The lower electrodes LE1, LE2, and LE3 are connected to the pixel circuits 1 (more specifically, the drain electrodes of the drive transistors 3 shown in FIG. 1) of the subpixels SP1, SP2, and SP3 through contact holes (not shown) provided in an organic insulating layer 12 to be described later, respectively. Each of the contact holes overlaps with the rib layer 5 and the partition 6.

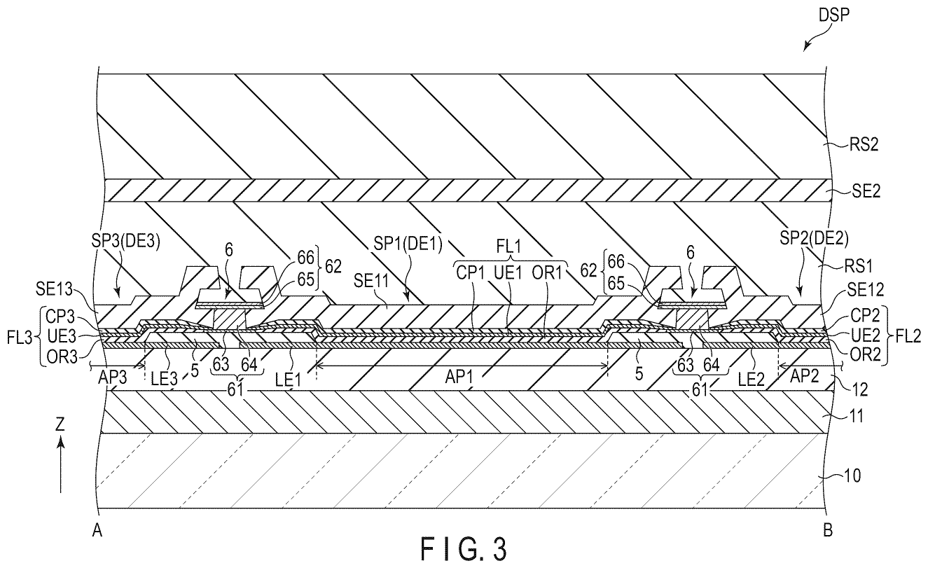

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuits 1, the scanning lines GL, the signal lines SL, and the power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The end portions of the lower electrodes LE1, LE2, and LE3 are covered with the rib layer 5.

The partition 6 includes a conductive lower portion 61 provided on the rib layer 5 and an upper portion 62 provided on the lower portion 61. The upper portion 62 has a width greater than that of the lower portion 61. Thus, the both end portions of the upper portion 62 protrude relative to the side surfaces of the lower portion 61. In other words, the partition 6 has an overhang shape in which the both end portions of the upper portion 62 protrude relative to the side surfaces of the lower portion 61.

In the example in FIG. 3, the lower portion 61 includes a bottom layer 63 and a stem layer 64. The bottom layer 63 is located between the stem layer 64 and the rib layer 5. Furthermore, in the example in FIG. 3, the upper portion 62 includes a first top layer 65 and a second top layer 66. The first top layer 65 is provided on the stem layer 64. The second top layer 66 is provided on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers which improve the extraction efficiency of the light emitted from the organic layers OR1, OR2, and OR3, respectively.

In the following descriptions, a multilayer body including the organic layer OR1, the upper electrode UE1, and the cap layer CP1 is referred to as a stacked film FL1, a multilayer body including the organic layer OR2, the upper electrode UE2, and the cap layer CP2 is referred to as a stacked film FL2, and a multilayer body including the organic layer OR3, the upper electrode UE3, and the cap layer CP3 is referred to as a stacked film FL3.

Sealing layers SE11, SE12, and SE13 which cover the stacked films FL1, FL2, and FL3, are provided in the subpixels SP1, SP2, and SP3, respectively. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example in FIG. 3, the sealing layer SE11 located on the partition 6 between the subpixels SP1 and SP2 is spaced apart from the sealing layer SE12 located on this partition 6. In addition, the sealing layer SE11 located on the partition 6 between the subpixels SP1 and SP3 is spaced apart from the sealing layer SE13 located on this partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least parts of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film or a cover glass may be further provided above the resin layer RS2. This cover member may be attached to the resin layer RS2 via, for example, an adhesive layer such as an optical clear adhesive (OCA).

The electrodes which constitute the above-mentioned touch panel may be provided on the sealing layer SE2. In addition, color filters corresponding to the colors of the subpixels SP1, SP2, and SP3 may be provided above the display elements DE1, DE2, and DE3, respectively.

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx) or silicon oxynitride (SiON). Each of the resin layers RS1 and RS2 is formed of, for example, a resinous material (organic insulating material) such as epoxy resin or acrylic resin.

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. In one example, each of the organic layers OR1, OR2, and OR3 comprises a structure in which a hole injection layer, a hole transport layer, an electron blocking layer, a light emitting layer, a hole blocking layer, an electron transport layer and an electron injection layer are stacked in order in a Z-direction. However, each of the organic layers OR1, OR2, and OR3 may comprise the other structure such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. In addition, these transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

A common voltage is applied to the partition 6. This common voltage is applied to each of the upper electrodes UE1, UE2, and UE3 which are in contact with the lower portions 61. Pixel voltages corresponding to the video signals of the signal lines SL are applied to the lower electrodes LE1, LE2, and LE3 through the pixel circuits 1 provided in the subpixels SP1, SP2, and SP3, respectively.

The organic layers OR1, OR2, and OR3 emit light based on the application of voltages. More specifically, when a potential difference is formed between the lower electrode LE1 and the upper electrode UE1, the light emitting layer of the organic layer OR1 emits light of the blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise color filters which convert the light emitted from the light emitting layers into light exhibiting the colors corresponding to the subpixels SP1, SP2, and SP3. Alternatively, the display device DSP may comprise a layer including a quantum dot which generates light exhibiting the colors corresponding to the subpixels SP1, SP2, and SP3 by the excitation caused by the light emitted from the light emitting layers.

The bottom layer 63 and the stem layer 64 are formed of, for example, a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may comprise a multilayer structure consisting of a plurality of layers. Alternatively, the stem layer 64 may include a layer formed of an insulating material. Furthermore, the lower portion 61 may comprise a single-layer structure formed of a conductive material.

For example, the first top layer 65 is formed of a metal material, and the second top layer 66 is formed of a transparent conductive oxide. For the metal material of the first top layer 65, for example, titanium, titanium nitride, molybdenum, tungsten, a molybdenum-tungsten alloy or a molybdenum-niobium alloy may be used. For the conductive oxide of the second top layer 66, for example, indium tin oxide (ITO), indium zinc oxide (IZO) or indium gallium zinc oxide (IGZO) may be used. Incidentally, the upper portion 62 may comprise a single-layer structure formed of a specific material. Moreover, the upper portion 62 may include a layer formed of an insulating material.

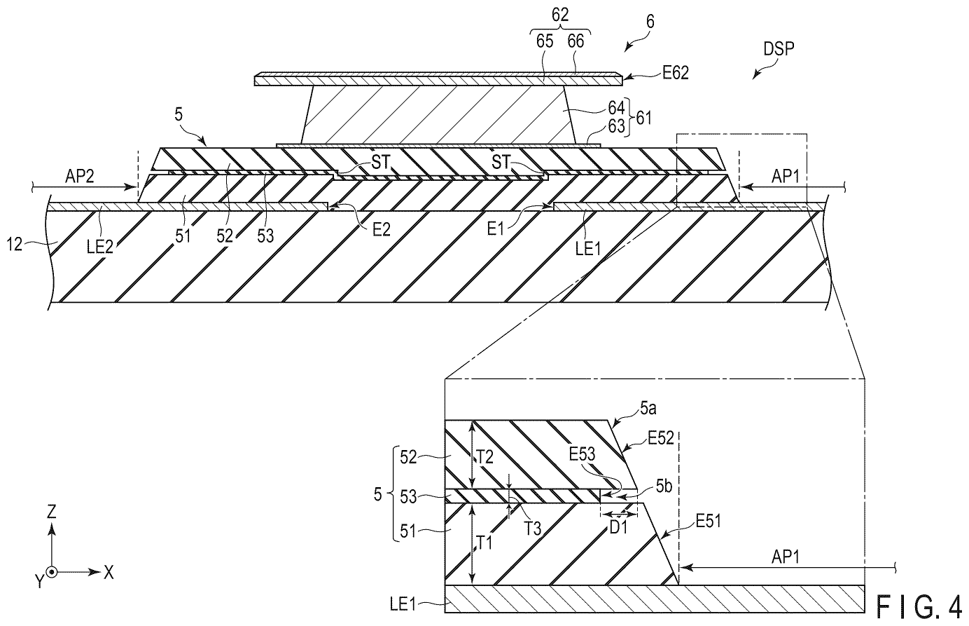

FIG. 4 is a schematic cross-sectional view showing the display device DSP along IV-IV line in FIG. 2. In this figure, the organic insulating layer 12, the rib layer 5, the partition 6, and the lower electrodes LE1 and LE2 are shown, and the other elements are omitted.

As shown in FIG. 4, the rib layer 5 includes a lower layer 51 provided on the organic insulating layer 12 and the lower electrodes LE1, LE2, and LE3, an upper layer 52 provided above the lower layer 51, and an intermediate layer 53 provided between the lower layer 51 and the upper layer 52.

As shown in FIG. 4, the both end portions E1 and E2 of the lower electrodes LE1 and LE2 are covered with the lower layer 51. Although not shown in the cross-sectional view of FIG. 4, an end portion E3 of the lower electrode LE3 is also covered with the lower layer 51. The lower layer 51 is in contact with the lower electrodes LE1 and LE2. Although not shown in the cross-sectional view of FIG. 4, the lower layer 51 is also in contact with the lower electrode LE3. The intermediate layer 53 is provided on the lower layer 51, and the upper layer 52 is provided on the intermediate layer 53.

The partition 6 is provided on the upper layer 52. The upper layer 52 is in contact with the lower portion 61 of the partition 6. In the example in FIG. 4, end portions of the bottom layer 63 of the partition 6 protrude from the side surfaces of the stem layer 64. The stem layer 64 is formed so as to be thicker than the bottom layer 63, the first top layer 65, and the second top layer 66.

As shown in FIG. 4, stepped portions ST caused by the end portions E1 and E2 of the lower electrodes LE1 and LE2 are generated on the upper surface of the lower layer 51, the lower surface of the upper layer 52, and the upper and lower surfaces of the intermediate layer 53. Although not shown in the cross-section of FIG. 4, the stepped portion ST caused by the end portion E3 of the lower electrode LE3 is also generated on the upper surface of the lower layer 51, the lower surface of the upper layer 52, and the upper and lower surfaces of the intermediate layer 53.

As shown in the enlarged view in FIG. 4, the lower layer 51 has an end portion E51, the upper layer 52 has an end portion E52, and the intermediate layer 53 has an end portion E53, in the vicinity of the pixel aperture AP1. The end portions E51 and E52 have a tapered shape in which the thickness gradually decreases. The end portion E52 is set back relative to the end portion E51. An inclined surface 5a is formed on the end portion of the rib layer 5 by the end portions E51 and E52. The inclined surface 5a forms the pixel aperture AP1. The end portion E51 of the lower layer 51 and the end portion E52 of the upper layer 52 protrude beyond the end portion E53 of the intermediate layer. Accordingly, a recess portion 5b is formed in the middle of the inclined surface 5a. The recess portion 5b is surrounded by the upper surface of the lower layer 51, the lower surface of the upper layer 52, and the side surface of the intermediate layer 53.

As shown in FIG. 4, the recess portion 5b has a depth D1. The depth D1 is equivalent to a length of protrusion of the upper layer 52 from the intermediate layer 53. The depth D1 of the recess portion 5b is greater than a thickness T3 of the intermediate layer 53. Accordingly, a hole injection layer HIL included in the organic layers OR1, OR2, and OR3, which will be described below, can be divided more reliably. In one example, the thickness T3 of the intermediate layer 53 is 30 nm, and the depth D1 of the recess portion 5b is greater than 30 nm, for example, 50 to 300 nm. However, the depth D1 and the thickness T3 are not limited to the examples mentioned here.

The structure of the rib layer 5 in the vicinity of the pixel aperture AP2 and the structure of the rib layer 5 in the vicinity of the pixel aperture AP3 are the same as the structure of the rib layer 5 in the vicinity of the pixel aperture AP1.

As shown in FIG. 2, the recess portion 5b surrounds the pixel apertures AP1, AP2, and AP3 in plan view. The recess portion 5b does not overlap with the end portion E62 of the upper portion 62 of the partition 6 in plan view.

The lower layer 51 and the upper layer 52 can be formed of an inorganic insulating material. The intermediate layer 53 can be formed of an inorganic insulating material having a higher etching rate than the lower layer 51 and the upper layer 52. For example, the lower layer 51 and the upper layer 52 can be formed of silicon oxynitride, and the intermediate layer 53 can be formed of silicon nitride or aluminum oxide.

In the example in FIG. 4, each of the thickness T1 of the lower layer 51 and the thickness T2 of the upper layer 52 is greater than the thickness T3 of the intermediate layer 53. In addition, in the example shown in FIG. 4, the thickness T1 is equal to the thickness T2. However, the thickness T1 may not be equal to the thickness T2.

In one example, the thickness T1 of the lower layer 51 is 250 nm, the thickness T2 of the upper layer 52 is 250 nm, and the thickness T3 of the intermediate layer 53 is 20 to 30 nm. However, the thicknesses T1, T2, and T3 are not limited to those mentioned here.

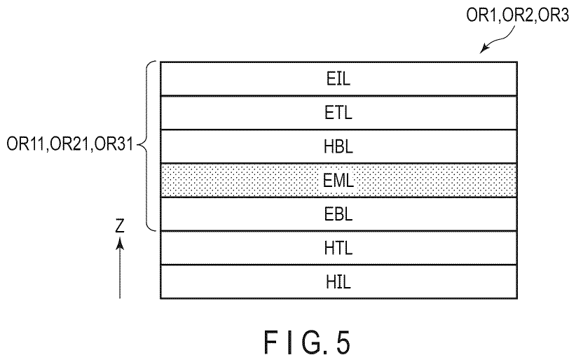

FIG. 5 is a diagram showing an example of a layer structure that can be applied to the organic layers OR1, OR2, and OR3 shown in FIG. 3.

The organic layers OR1, OR2, and OR3 include a hole injection layer HIL and a hole transport layer HTL. In addition, the organic layer OR1 further includes an organic layer OR11, the organic layer OR2 further includes an organic layer OR21, and the organic layer OR3 further includes an organic layer OR31. The organic layer OR1 has, for example, a structure in which the hole injection layer HIL, the hole transport layer HTL, and the organic layer OR11 are sequentially stacked in the third direction Z. The organic layer OR2 has, for example, a structure in which the hole injection layer HIL, the hole transport layer HTL, and the organic layer OR21 are sequentially stacked in the third direction Z. The organic layer OR3 has, for example, a structure in which the hole injection layer HIL, the hole transport layer HTL, and the organic layer OR31 are sequentially stacked in the third direction Z.

Each of the organic layers OR11, OR21, and OR31 has, for example, a structure in which the electron blocking layer EBL, the light emitting layer EML, the hole blocking layer HBL, the electron transport layer ETL, and the electron injection layer EIL are sequentially stacked in the third direction Z.

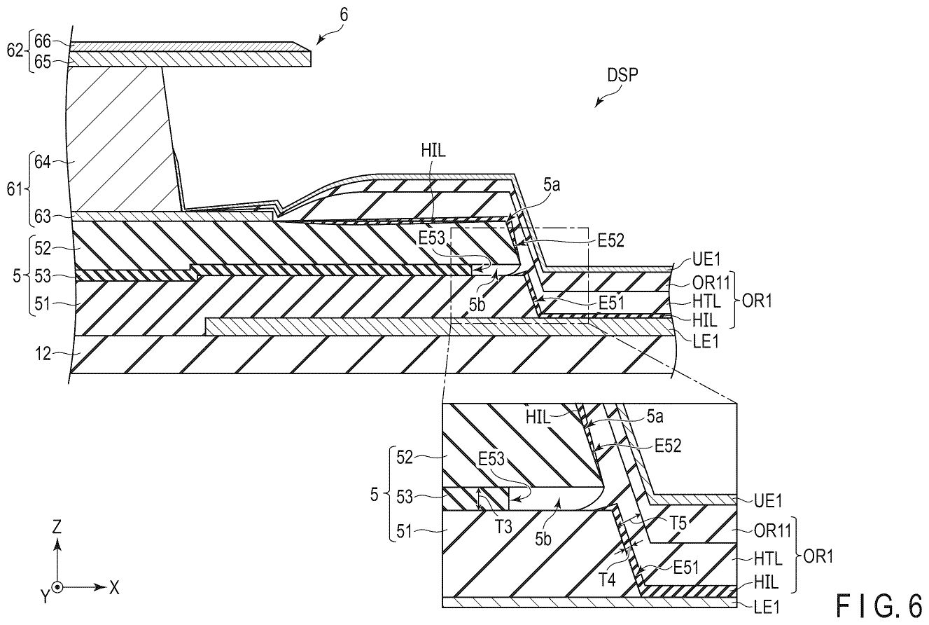

FIG. 6 is a schematic cross-sectional view showing the display device DSP along V-V line in FIG. 2. In this figure, the organic insulating layer 12, the rib layer 5, the partition 6, the lower electrode LE1, the organic layer OR1, and the upper electrode UE1 are shown, and the other elements are omitted.

The organic layer OR1 includes the hole injection layer HIL, the hole transport layer HTL, and the organic layer OR11, which are sequentially stacked in the third direction Z. The organic layer OR11 comprises an electron blocking layer EBL, an emissive layer EML, a hole blocking layer HBL, an electron transport layer ETL, and an electron injection layer EIL, which are sequentially stacked in the third direction Z. The hole transport layer HTL among these layers is the thickest. The thickness of the hole transport layer HTL is, for example, half the thickness of the entire organic layer OR1 or greater.

As shown in FIG. 6, the hole injection layer HIL covers the inclined surface 5a at the end portion of the rib layer 5 and also covers the upper surface of the upper layer 52 of the rib layer 5. In the example shown in FIG. 6, the hole injection layer HIL is not contact with the partition 6 and, more specifically, the hole injection layer HIL is spaced apart from the end portion of the bottom layer 63 of the lower portion 61. Incidentally, the hole injection layer HIL may be in contact with the partition 6.

As shown in FIG. 6, the hole transport layer HTL covers the hole injection layer HIL and also covers the end portion of the bottom layer 63 of the lower portion 61. The organic layer OR11 covers the hole transport layer HTL. The upper electrode UE1 covers the organic layer OR11 and is in contact with at least one of the bottom layer 63 and the stem layer 64 of the lower portion 61. In the example shown in FIG. 6, the upper electrode UE1 is in contact with the stem layer 64. The thicknesses of the hole injection layer HIL, the hole transport layer HTL, and the organic layer OR11 decrease as they are closer to the side surface of the stem layer 64 of the lower portion 61.

As shown in the enlarged view of FIG. 6, a part of the hole injection layer HIL enters the recess portion 5b formed in the middle of the inclined surface 5a, causing the hole injection layer HIL to be divided in the recess portion 5b. In addition, a part of the hole transport layer HTL enters the recess portion 5b, blocking the entrance of the recess portion 5b. The hole transport layer HTL is not divided by the recess portion 5b.

The thickness T3 of the intermediate layer 53 is greater than the thickness T4 of the hole injection layer HIL on the inclined surface 5a. Accordingly, the hole injection layer HIL can be divided more reliably. In addition, the thickness T3 of the intermediate layer 53 is smaller than the total thickness T5 of the hole injection layer HIL and the hole transport layer HTL on the inclined surface 5a. Accordingly, the division of the upper electrode UE1 formed above the hole transport layer HTL in the recess portion 5b can be suppressed.

The organic layers OR2 and OR3 and the upper electrodes UE2 and UE3 comprise the same structure as the organic layer OR1 and the upper electrode UE1 shown in FIG. 5. However, the thicknesses of each layer layer included in the organic layers OR1, OR2, and OR3 may be different.

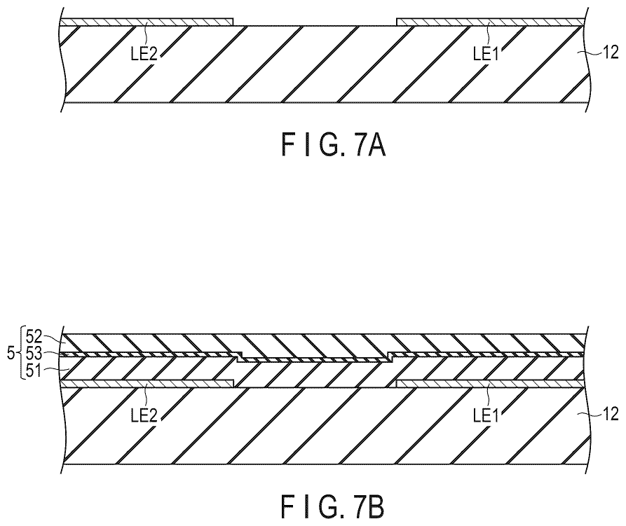

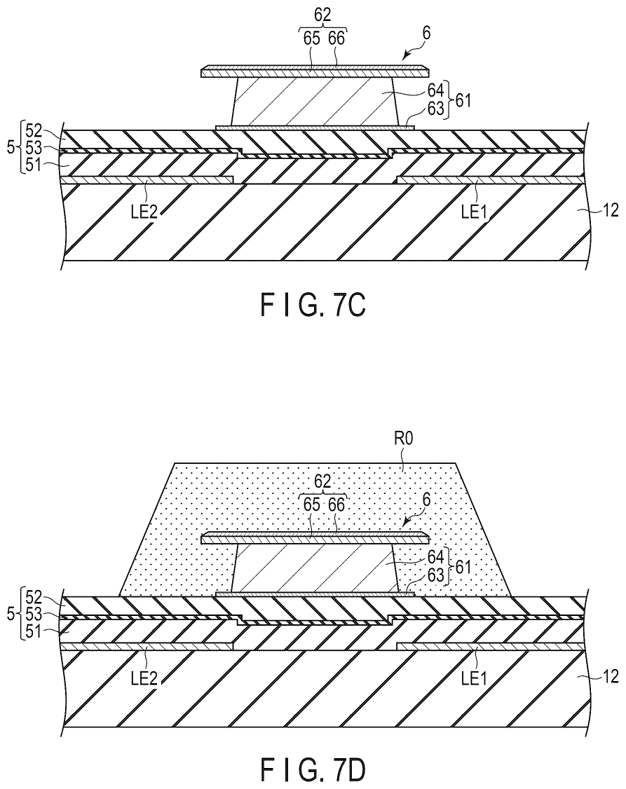

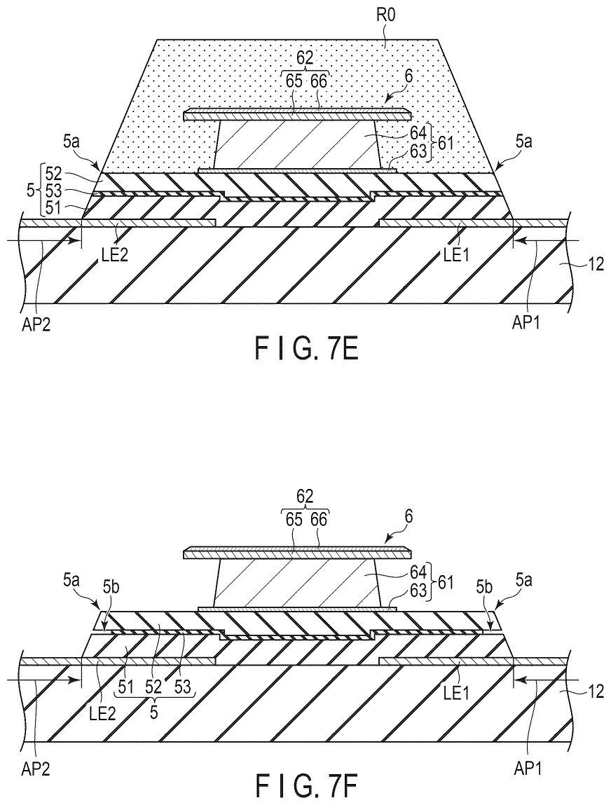

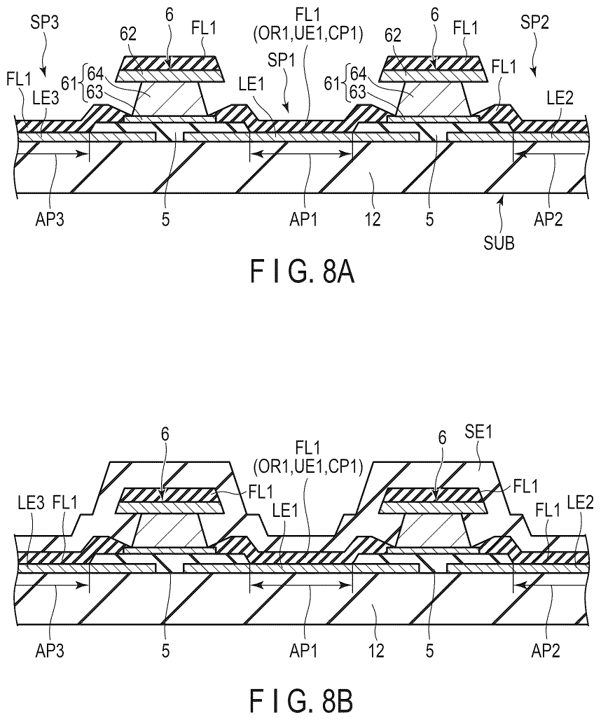

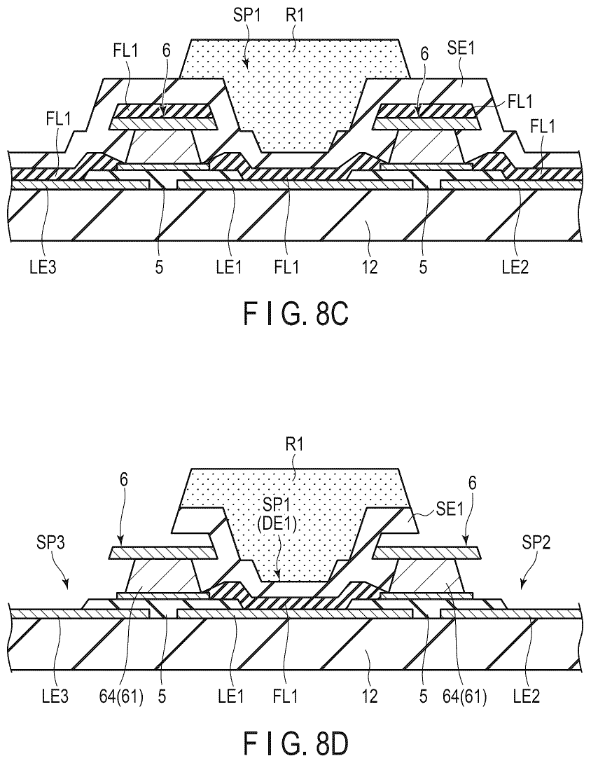

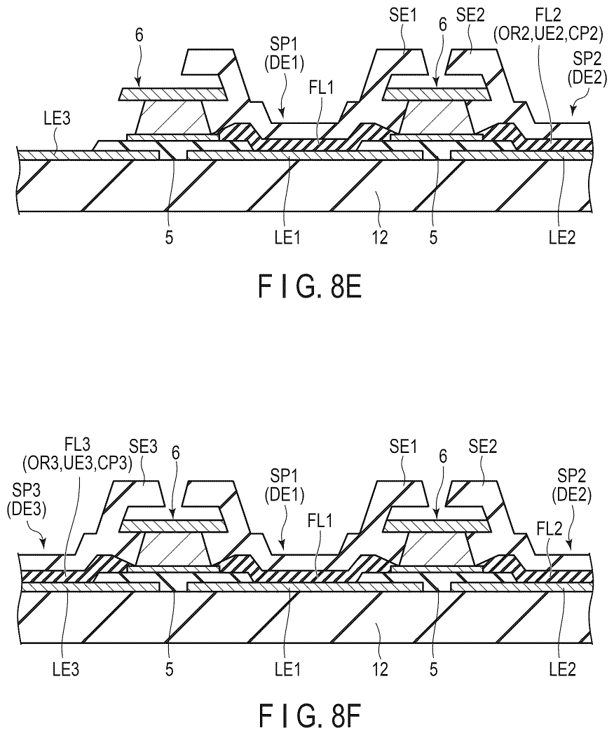

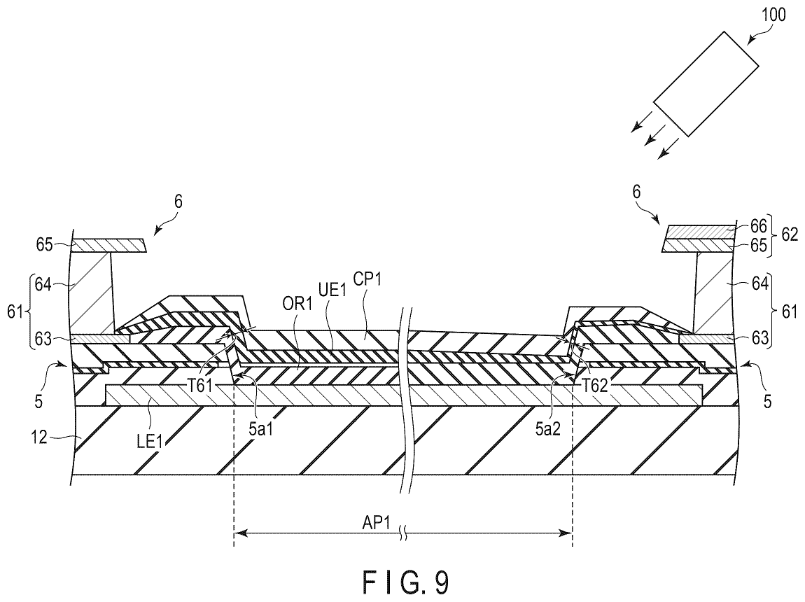

Next, an example of a method of manufacturing the display device DSP will be described. FIG. 7A to FIG. 7F, FIG. 8A to FIG. 8F, and FIG. 9 are schematic cross-sectional views showing manufacturing processes of the display device DSP. FIG. 7A to FIG. 7F correspond to the cross-section along the IV-IV line in FIG. 2, and FIG. 8A to FIG. 8F correspond to the cross-section along the III-III line in FIG. 2. In these figures, illustrations of the substrate 10 and the circuit layer 11 are omitted.

To manufacture the display device DSP, first, the circuit layer 11 is formed on the substrate 10. Furthermore, the organic insulating layer 12 including the contact holes is formed on the circuit layer 11.

After the organic insulating layer 12 is formed, the lower electrodes LE1, LE2, and LE3 are formed on the organic insulating layer 12 as shown in FIG. 7A.

After the lower electrodes LE1, LE2, and LE3 are formed, the lower layer 51 covering the lower electrodes LE1, LE2, and LE3 is formed, the intermediate layer 53 covering the lower layer 51 is formed, the upper layer 52 covering the intermediate layer 53 is formed, and the rib layer 5 is formed as shown in FIG. 7B.

After the rib layer 5 is formed, the partition 6 including the lower portion 61 and the upper portion 62 is formed on the rib layer 5 as shown in FIG. 7C. The lower portion 61 includes the bottom layer 63 and the stem layer 64 as shown in FIG. 3. In addition, the upper portion 62 includes the first top layer 65 and the second top layer 66 as shown in FIG. 3.

After the partition 6 is formed, a resist R0 having a shape corresponding to the rib layer 5 is provided on the upper layer 52 as shown in FIG. 7D. The resist R0 covers the partition 6. Furthermore, the rib layer 5 is etched.

The etching of the rib layer 5 will be described. First, a case where the lower layer 51 and the upper layer 52 are formed of silicon oxynitride and that the intermediate layer 53 is formed of silicon nitride will be described. First, anisotropic dry etching is performed as the first etching to remove a part of the rib layer 5, which is exposed from the resist R0, as shown in FIG. 7E. Next, isotropic dry etching is performed as the second etching to form the recess portion 5b as shown in FIG. 7F. The material used to form the intermediate layer 53 has a higher etching rate in the second dry etching than the materials used to form the lower layer 51 and the upper layer 52. As a result, the intermediate layer 53 is more eroded than the lower layer 51 and the upper layer 52, forming the recess portion 5b on the inclined surface 5a. Alternatively, the recess portion 5b may be formed by performing anisotropic dry etching as the first etching and wet etching using dilute hydrofluoric acid as the second etching. The material used to form the intermediate layer 53 has a higher etching rate in the second dry etching than the materials used to form the lower layer 51 and the upper layer 52. As a result, the intermediate layer 53 is more eroded than the lower layer 51 and the upper layer 52, forming the recess portion 5b on the inclined surface 5a, as shown in FIG. 7F. However, by performing both the first etching and the second etching as dry etching, the first etching and the second etching can be processed as a single continuous process. The process for etching the rib layer 5 can be thereby simplified.

Next, a case where the lower layer 51 and upper layer 52 are formed of silicon oxynitride and the intermediate layer 53 is formed of aluminum oxide will be described. First, anisotropic dry etching is performed as the first etching to remove the part of the upper layer 52, which is exposed from the resist R0. Next, wet etching using dilute hydrofluoric acid is performed as the second etching to remove the part of the intermediate layer 53, which is exposed from the resist R0. The material used to form the intermediate layer 53 has a higher etching rate in the second etching than the materials used to form the lower layer 51 and upper layer 52. For this reason, the end portion of the intermediate layer 53 is more eroded than the end portion of the upper layer 52. Next, anisotropic dry etching is performed as the third etching to remove the part of the lower layer 51, which is exposed from the resist R0. Accordingly, recess portions 5b are formed on the inclined surfaces 5a as shown in FIG. 7F. After the rib layer 5 is thus etched, the resist R0 is removed as shown in FIG. 7F.

Next, processes for forming the display elements DE1, DE2, and DE3 are performed. In the present embodiment, it is assumed that the display element DE1 is first formed, then the display element DE2 is formed, and the display element DE3 is finally formed. However, the order of formation of the display elements DE1, DE2, and DE3 is not limited to this example.

To form the display element DE1, first, the stacked film FL1 is formed over the display area DA and the surrounding area SA as a whole, as shown in FIG. 8A. As shown in FIG. 3, the stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1. The stacked film FL1 is divided into a plurality of portions by the partition 6 having an overhang shape. The organic layer OR1, the upper electrode UE1, and the cap layer CP1 are formed by vapor deposition.

After the stacked film FL1 is formed, the sealing layer SE11 is formed over the display area DA and the surrounding area SA as a whole, as shown in FIG. 8B. The sealing layer SE1 is formed by CVD. The sealing layer SE1 continuously covers the portions into which the stacked film FL1 is divided, and the partition 6.

After the sealing layer SE11 is formed, the resist R1 is formed on the sealing layer SE11 as shown in FIG. 8C. The resist R1 covers subpixel SP1 and a part of the partition 6 around the subpixel.

After that, the portions of the stacked film FL1 and the sealing layer SE11, which are exposed from the resist R1, are removed by etching using the resist R1 as a mask, as shown in FIG. 8D. Accordingly, the display element DE1 is formed in the subpixel SP1. For example, the etching includes wet etching and dry etching which are sequentially performed for the sealing layer SE11, the cap layer CP1, the upper electrode UE1, and the organic layer OR1. After these etching processes, the resist R1 is removed.

The display elements DE2 and DE3 are formed in the same procedures as the procedure of the display element DE1. In other words, to form the display element DE2, the stacked film FL2 and the sealing layer SE12 are formed over the display area DA and the surrounding area SA as a whole. As shown in FIG. 3, the stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2. By patterning the stacked film FL2 and the sealing layer SE12, the display element DE2 is formed in the subpixel SP2 as shown in FIG. 8E.

In addition, to form the display element DE3, the stacked film FL3 and the sealing layer SE13 are formed over the display area DA and the surrounding area SA as a whole. As shown in FIG. 3, the stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3. By patterning the stacked film FL3 and the sealing layer SE13, the display element DE3 is formed in the subpixel SP3 as shown in FIG. 8F.

After the display elements DE1, DE2, and DE3 are formed, the resin layer RS1, the sealing layer SE2, and the resin layer RS2 shown in FIG. 3 are sequentially formed. The display device DSP is completed through the processes.

In the formation of the stacked film FL1 shown in FIG. 8A, the upper electrode UE1 can be formed by, for example, applying an oblique vapor deposition method of performing vapor deposition from a direction oblique to the normal (third direction Z) of the substrate 10. For example, as shown in FIG. 9, when a deposition source 100 is provided at the upper right to deposit an upper electrode material, the upper electrode material adheres thickly to the inclined surface 5a1 (first inclined surface) that faces the deposition source 100. Accordingly, division of the upper electrode UE1 on the inclined surface 5a1 can be suppressed.

When the upper electrode material is deposited as shown in FIG. 9, the same pixel aperture AP1 as the inclined surface 5a1 is formed, and the upper electrode material adheres thinly to the inclined surface 5a2 (second inclined surface) which is opposite to the inclined surface 5a1. In other words, the thickness T61 of the upper electrode UE1 formed on the inclined surface 5a1 is greater than the thickness T62 of the upper electrode UE1 formed on the inclined surface 5a2.

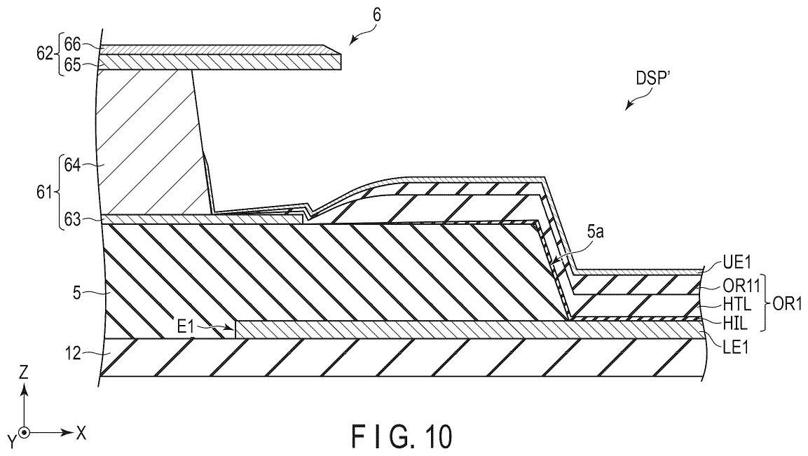

FIG. 10 is a cross-sectional view showing a display device DSP′ of a comparative example.

The display device DSP′ of the comparative example shown in FIG. 10 is different from the display device DSP shown in FIG. 3 to FIG. 6 in that the recess portions 5b are not formed on the inclined surfaces 5a of the rib layer 5, which form the pixel apertures AP1, AP2, and AP3.

In the display device DSP′ shown in FIG. 10, when the hole injection layer HIL of the organic layers OR1, OR2, and OR3 comes into contact with the conductive lower portion 61, a leakage current flows from the lower electrodes LE1, LE2, and LE3 to the lower portion 61 through the hole injection layer HIL without passing through layers such as the light emitting layer EML, which may cause display failure.

In contrast, in the display device DSP of the present embodiment, recess portions 5b are formed on the inclined surfaces 5a of the rib layer 5, which form the pixel apertures AP1, AP2, and AP3. The hole injection layer HIL can be thereby divided at the recess portion 5b. Therefore, even if the hole injection layer HIL comes into contact with the conductive lower portion 61, an undesired leakage current flowing from the lower electrodes LE1, LE2, and LE3 to the lower portion 61 can be suppressed and, consequently, display failure which results from the leakage current can be suppressed. Thus, the display device DSP of the present embodiment can suppress the reduction in reliability.

As described above, when the depth D1 of the recess portion 5b is greater than the thickness T1 of the lower layer 51, the hole injection layer HIL can be divided more reliably.

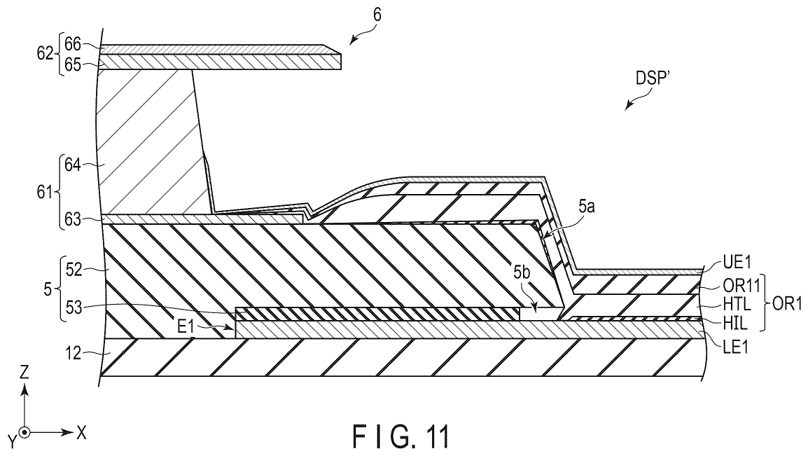

FIG. 11 is a cross-sectional view showing a display device DSP′ of another comparative example.

The display device DSP′ shown in FIG. 11 is different from the display device DSP shown in FIG. 3 to FIG. 6 in that the rib layer 5 does not include the lower layer 51, and the end portions E51 and E52 of the lower layer 51 and the upper layer 52 protrude beyond the end portion E53 of the intermediate layer 53 such that the recess portion 5b is not formed in the middle of the inclined surface 5a.

In the display device DSP′ shown in FIG. 11, the recess portion 5b is surrounded by the lower surface of the upper layer 52, the side surface of the intermediate layer 53, and the upper surface of the lower electrode LE1. In the manufacturing of such a display device DSP′, if the etching during formation of the recess portion 5b is excessive, the depth D1 of the recess portion 5b may become too large, and the end portions (E1, E2, and E3) of the lower electrodes LE1, LE2, and LE3 may be exposed. The exposed end portions (E1, E2, and E3) of the lower electrodes LE1, LE2, and LE3, which are exposed in subsequent manufacturing processes, may be damaged or display failure may occur due to moisture penetration.

In the display device DSP of the present embodiment, the end portions E1, E2, and E3 of the lower electrodes LE1, LE2, and LE3 are covered with the lower layer 51. Therefore, even if the etching during the formation of the recess portion 5b is excessive, the end portions (E1, E2, and E3) of the lower electrodes LE1, LE2, and LE3 are not exposed and, consequently, display failure which results from the excessive etching can be suppressed. Thus, the display device DSP of the present embodiment can suppress the reduction in reliability.

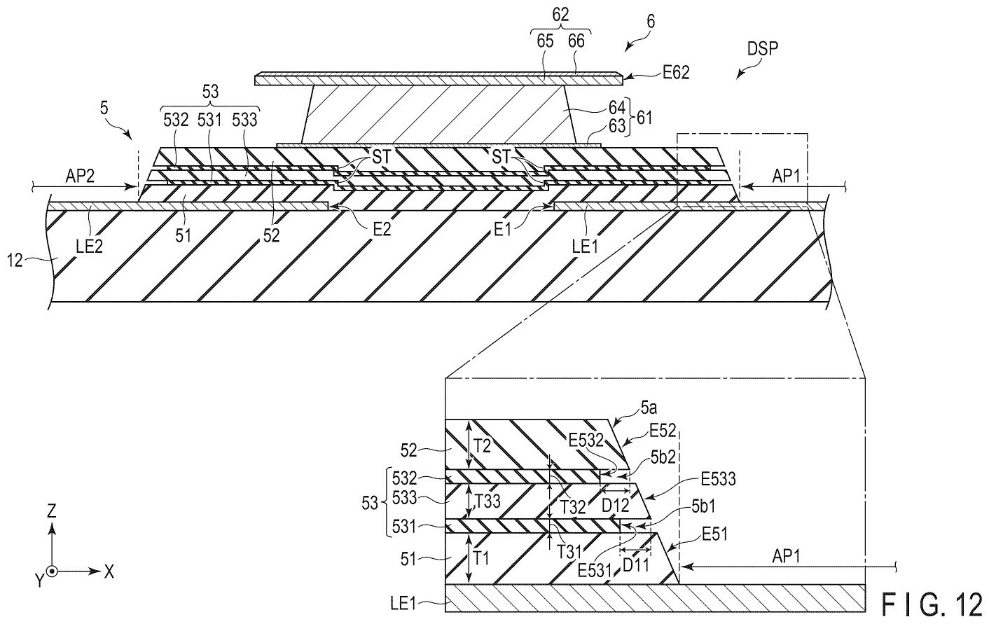

FIG. 12 is a schematic cross-sectional view showing another configuration example of the display device DSP shown in FIG. 4. FIG. 12 is a schematic cross-sectional view showing the display device DSP along IV-IV line in FIG. 2. In this figure, the organic insulating layer 12, the rib layer 5, the partition 6, and the lower electrodes LE1 and LE2 are shown, and the other elements are omitted. Description of the same configuration as the display device DSP shown in FIG. 4 will be replaced with the above description and will be omitted.

As shown in FIG. 12, the rib layer 5 includes a lower layer 51 provided on the organic insulating layer 12 and the lower electrodes LE1, LE2, and LE3, an upper layer 52 provided above the lower layer 51, and an intermediate layer 53 provided between the lower layer 51 and the upper layer 52. The intermediate layer 53 comprises a first intermediate layer 531 provided on the lower layer 51, a second intermediate layer 532 provided between the first intermediate layer 531 and the upper layer 52, and a third intermediate layer 533 provided between the first intermediate layer 531 and the second intermediate layer 532.

As shown in FIG. 12, the first intermediate layer 531 is provided on the lower layer 51, the third intermediate layer 533 is provided on the first intermediate layer 531, the second intermediate layer 532 is provided on the third intermediate layer 533, and the upper layer 52 is provided on the second intermediate layer 532.

As shown in FIG. 12, the stepped portions ST caused by the end portions E1 and E2 of the lower electrodes LE1 and LE2 are generated on the upper surface of the lower layer 51, the lower surface of the upper layer 52, and the upper and lower surfaces of the first intermediate layer 531, the second intermediate layer 532, and the third intermediate layer 533. Although not shown in the cross-section of FIG. 4, the stepped portion ST caused by the end portion E3 of the lower electrode LE3 is also generated on the upper surface of the lower layer 51, the lower surface of the upper layer 52, and the upper and lower surfaces of the first intermediate layer 531, the second intermediate layer 532, and the third intermediate layer 533.

As shown in an enlarged view in FIG. 12, the lower layer 51 has an end portion E51, the upper layer 52 has an end portion E52, the first intermediate layer 531 has an end portion E531, the second intermediate layer 532 has an end portion E532, and the third intermediate layer 533 has an end portion E533. The end portions E51, E52, and E533 have a tapered shape in which the thickness gradually decreases. The end portion E533 is set back relative to the end portion E51, and the end portion E52 is set back relative to the end portion E533. An inclined surface 5a is formed on the end portion of the rib layer 5 by the end portions E51, E52, and E533. The inclined surface 5a forms the pixel aperture AP1.

The end portion E51 of the lower layer 51 and the end portion E533 of the third intermediate layer 533 protrude beyond the end portion E531 of the first intermediate layer 531. Accordingly, a recess portion 5b1 (first recess) is formed in the middle of the inclined surface 5a. In addition, the end portion E533 of the third intermediate layer 533 and the end portion E52 of the upper layer 52 protrude beyond the end portion E532 of the second intermediate layer 532. Accordingly, a recess portion 5b2 (second recess) is formed in the middle of the inclined surface 5a. In other words, two recess portions 5b1 and 5b2 are formed in the middle of the inclined surface 5a. The recess portions 5b1 and 5b2 surround the pixel apertures AP1, AP2, and AP3 in plan view. The recess portions 5b1 and 5b2 do not overlap with the end portion of the upper portion 62 of the partition 6 in plan view.

By forming two recess portions 5b1 and 5b2 in the middle portion of the inclined surface 5a, the hole injection layer HIL included in the organic layers OR1, OR2, and OR3 can be divided more reliably.

In the example shown in FIG. 12, two recess portions 5b are formed in the middle of the inclined surface 5a. However, two or more recess portions 5b may be formed on the inclined surface 5a.

As shown in FIG. 12, the recess portions 5b1 and 5b2 have depths D11 and D12, respectively. The depth D11 is equivalent to a length of protrusion of the third intermediate layer 533 from the first intermediate layer 531, and the depth D12 corresponds to a length of protrusion of the upper layer 52 from the second intermediate layer 532. In the example shown in FIG. 12, the depths D11 and D12 are equal, but may not be equal. The depth D11 is greater than a thickness T31 of the first intermediate layer 531, and the depth D12 is greater than a thickness T32 of the second intermediate layer 532. Accordingly, a hole injection layer HIL included in the organic layers OR1, OR2, and OR3, which will be described below, can be divided more reliably.

In one example, in one example, the thicknesses T31 and T32 of the first intermediate layer 531 and the second intermediate layer 532 are 30 nm, and the depths D11 and D12 of the recess portions 5b1 and 5b2 are greater than 30 nm, for example, 50 to 300 nm. However, the depths D12 and D11 and the thicknesses T31 and T32 are not limited to those mentioned here.

The lower layer 51, the upper layer 52, and the third intermediate layer 533 can be formed of an inorganic insulating material. The first intermediate layer 531 and second intermediate layer 532 can be formed of an inorganic insulating material having a higher etching rate than the lower layer 51, the upper layer 52, and the third intermediate layer 533. For example, the lower layer 51, the upper layer 52, and the third intermediate layer 533 can be formed of silicon oxynitride, and the first intermediate layer 531 and second intermediate layer 532 can be formed of silicon nitride or aluminum oxide.

In the example shown in FIG. 12, each of the thickness T1 of the lower layer 51, the thickness T2 of the upper layer 52, and the thickness T33 of the third intermediate layer 533 is greater than the thickness T31 of the first intermediate layer 531 and the thickness T32 of the second intermediate layer 532. In addition, in the example shown in FIG. 12, the thicknesses T1 and T2 are greater than the thickness T33. However, the thicknesses T1, T2, and T33 may be equal to one another.

The structure of the rib layer 5 in the vicinity of the pixel aperture AP2 and the structure of the rib layer 5 in the vicinity of the pixel aperture AP3 are the same as the structure of the rib layer 5 in the vicinity of the pixel aperture AP1.

In this configuration example, the same advantages as those of the display device DSP shown in FIG. 4 can also be obtained.

As described above, according to the present embodiment, a display device capable of suppressing the reduction in reliability can be provided.

All of the manufacturing methods of a display device that can be implemented by a person of ordinary skill in the art through arbitrary design changes to the manufacturing method described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a substrate;
an organic insulating layer provided above the substrate;
a lower electrode provided above the organic insulating layer;
a rib layer covering an end portion of the lower electrode and including a pixel aperture overlapping with the lower electrode;
an organic layer covering the lower electrode through the pixel aperture and emitting light in accordance with application of a voltage;
an upper electrode covering the organic layer; and
a partition including a lower portion provided on the rib layer and an upper portion having an end portion protruding from a side surface of the lower portion, wherein
the rib layer comprises:
an upper layer which is in contact with the lower portion of the partition;
a lower layer which covers the end portion of the lower electrode and which is in contact with the lower electrode;
an intermediate layer provided between the upper layer and the lower layer; and
an inclined surface forming the pixel aperture, and
end portions of the upper layer and the lower layer protrude beyond an end portion of the intermediate layer, thereby forming a recess portion on the inclined surface.

2. The display device of claim 1, wherein
a depth of the recess portion is greater than a thickness of the intermediate layer.

3. The display device of claim 1, wherein
the recess portion does not overlap with the end portion of the upper portion of the partition in plan view.

4. The display device of claim 1, wherein
the recess portion surrounds the pixel aperture in plan view.

5. The display device of claim 1, wherein
the upper layer and the lower layer are formed of an inorganic insulating material, and
the intermediate layer is formed of an inorganic insulating material having a higher etching rate than the upper layer and the lower layer.

6. The display device of claim 5, wherein
the upper layer and the lower layer are formed of silicon oxynitride, and
the intermediate layer is formed of silicon nitride or aluminum oxide.

7. The display device of claim 1, wherein
the organic layer is composed of a plurality of layers including a hole injection layer covering the lower electrode and a hole transport layer covering the hole injection layer.

8. The display device of claim 7, wherein
the organic layer covers the inclined surface of the rib layer, and
the hole injection layer is divided by the recess portion of the inclined surface.

9. The display device of claim 8, wherein
the hole transport layer is not divided by the recess portion of the inclined surface.

10. The display device of claim 1, wherein
the inclined surface includes a first inclined surface and a second inclined surface that form the same pixel aperture and that face each other,
the organic layer covers the first inclined surface and the second inclined surface,
the upper electrode covers the organic layer, and
a thickness of the upper electrode formed on the first inclined surface is greater than a thickness of the upper electrode formed on the second inclined surface.

11. The display device of claim 7, wherein
a thickness of the intermediate layer is greater than a thickness of the hole injection layer, and is smaller than a sum of the thicknesses of the hole injection layer and the hole transport layer.

12. The display device of claim 1, wherein
the lower portion of the partition comprises a conductive bottom layer provided above the rib layer and a conductive stem layer provided on the bottom layer.

13. The display device of claim 12, wherein
the end portion of the bottom layer protrudes from the side surfaces of the stem layer.

14. The display device of claim 12, wherein
the upper electrode is in contact with at least the bottom layer and the stem layer.

15. A display device comprising:
a substrate;
an organic insulating layer provided above the substrate;
a lower electrode provided above the organic insulating layer;
a rib layer covering an end portion of the lower electrode and including a pixel aperture overlapping with the lower electrode;
an organic layer covering the lower electrode through the pixel aperture and emitting light in accordance with application of a voltage;
an upper electrode covering the organic layer; and
a partition including a lower portion provided on the rib layer and an upper portion having an end portion protruding from a side surface of the lower portion, wherein
the rib layer comprises:
an upper layer which is in contact with the lower portion of the partition;
a lower layer which covers the end portion of the lower electrode and which is in contact with the lower electrode;
an intermediate layer provided between the upper layer and the lower layer; and
an inclined surface forming the pixel aperture,
the intermediate layer comprises a first intermediate layer which is in contact with the lower layer, a second intermediate layer which is in contact with the upper layer, and a third intermediate layer provided between the first intermediate layer and the second intermediate layer,
end portions of the lower layer and the third intermediate layer protrude beyond an end portion of the first intermediate layer, thereby forming a first recess portion on the inclined surface, and
end portions of the upper layer and the third intermediate layer protrude beyond an end portion of the second intermediate layer, thereby forming a second recess portion on the inclined surface.

16. The display device of claim 15, wherein
the upper layer, the lower layer, and the third intermediate layer are formed of an inorganic insulating material, and
the first intermediate layer and the second intermediate layer are formed of an inorganic insulating material having a higher etching rate than the upper layer, the lower layer, and the third intermediate layer.

17. The display device of claim 16, wherein
the third intermediate layer is formed of the same inorganic insulating material as the upper layer and the lower layer.

18. The display device of claim 17, wherein
the upper layer, the lower layer, and the third intermediate layer are formed of silicon oxynitride, and
the first intermediate layer and the second intermediate layer are formed of silicon nitride or aluminum oxide.

19. The display device of claim 15, wherein
a thickness of the third intermediate layer is smaller than thicknesses of the upper layer and the lower layer.

20. The display device of claim 15, wherein
a depth of the first recess portion is greater than a thickness of the first intermediate layer, and a depth of the second recess portion is greater than a thickness of the second intermediate layer.
